(19) United States
(12) Patent Application Publication
(10) Pub. No.: US 2002/0140105 A1
(43) Pub. Date: Oct. 3, 2002

(54) High strength vias

(76) Inventors: Leo M. Higgins III, Austin, TX (US); Luc Boone, Oostkamp (BE); Jozef van Puymbroeck, Oostkamp (BE)

Correspondence Address: LAURA M. SLENZAK, SIEMENS CORPORATION, 186 WOOD AVENUE SOUTH, ISELIN, NJ, 08830, US

(21) Appl. No.: 10/077,728

(22) Filed: Feb. 15, 2002

Related U.S. Application Data
(60) Provisional application No. 60/269,420, filed on Feb. 16, 2001.

(51) Int. Cl. H01L 23/48

(52) U.S. Cl. 257/774

(57) ABSTRACT

A interconnection circuit includes a dielectric plane having conductors fabricated from copper disposed on each side of the dielectric plane. An opening known as a via disposed through the dielectric plane includes a conductive link between the conductors disposed on either side of the dielectric plane. The conductive link includes a first layer fabricated from copper and a second layer of Nickel disposed over the copper layer to strengthen the first layer and prevent fractures known as barrel cracks in the conductive link. A third layer composed of Gold is deposited over the second layer to protect the second layer of Nickel from corrosion. In another embodiment of the subject invention the third layer is composed of an easily cleaned or removed metal and a coating of Gold is deposited in specific discrete locations to facilitate wire bonding or soldering.

The application claims priority to U.S. Provisional application Serial No. 60/269,420, filed on Feb. 16, 2001.

### BACKGROUND OF THE INVENTION

This invention relates to a high strength conductive link for interconnecting conductors disposed on opposite sides of a dielectric plane existing in an interconnection circuit.

Typically, an interconnection circuit includes a conductor material of a specific pattern to form a circuit. The patterned conductor material is disposed on both sides of a dielectric plane. An opening through the dielectric plane includes a conductive link to provide an electrical connection between elements of the conductor patterns on both sides of the dielectric plane. The conductive link is simply a layer of the conductor that is applied to the inner walls of the opening to provide the electrical connection between the conductor patterns on both sides of the dielectric plane. Typically, the conductor is fabricated from a copper material. The dielectric plane and the conductor expand at differing rates with changes in temperature and can cause fractures in the conductive link known in the art as barrel cracking. Increasing the material thickness of the conductor material on the inner walls of the conductive link can prevent cracks in the conductive link. However, this solution is limited to circuit assemblies having sufficient space for the increased thickness conductor. In circuit assemblies having smaller holes known in the art as vias or microvias, increasing the thickness of the conductor is not feasible.

In the fabrication of interconnection circuits having conductive links which would be large enough to allow the necessary increase in the thickness of the conductor adhering to the inner walls of the link, increasing the conductor thickness still may not be desirable.

The ability to create fine conductor line and spaces on the surface or surfaces of the dielectric plane in the interconnection circuit is a function of the conductor thickness on the dielectric plane surfaces. Often the cost effective manufacturing processes used to add to the thickness of the conductor lining the conductive line will increase the thickness of the conductor plane on the surface or surfaces of the dielectric plane in the interconnection circuit. Generally as the thickness of the conductor on the surface of the dielectric plane increases, the size of the minimum conductor line width and the size of the minimum space between conductors increases. Thus if a finer conduct line and space is desired on the surface or surfaces of the dielectric plane, the elimination of fractures in the conductive link conductor by increasing conductor thickness may not be permitted.

For these reasons it is desirable to develop a conductive link for a dielectric plane in an interconnection circuit having increased strength to prevent cracking and fractures in the conductive link.

### SUMMARY OF THE INVENTION

The invention is a interconnection circuit having a conductive link disposed through a dielectric plane and coated with a strengthening metal layer to substantially prevent fractures in the conductive link.

The interconnection circuit includes a dielectric plane having first and second sides and conductors disposed on each of the sides. The conductors are electrically connected by a conductive link disposed within an opening of the dielectric plane. The opening with the conductive link is known in the art as a via or microvia. The conductive link is preferably copper and coats inner walls of the opening. The dielectric plane material and the copper have different rates of thermal expansion that can cause fractures in the conductive link known in the art as barrel cracking. A second layer of metal is disposed over the copper to substantially prevent fracturing of the conductive link. Preferably the second layer of metal is nickel. A third layer of metal material is disposed over the second layer to provide corrosion resistance to the nickel surface. The third layer preferably is composed of gold, silver, palladium, or other metals that offer a high degree of corrosion resistance. In an alternate embodiment the third layer is composed of copper. Corrosion occurring on the second layer of copper is easily removed and thereby provides a desirable option to the use of the expensive corrosion resistant metals, such as Au, Ag, and Pd.

The invention provides a strengthened conductive link for a interconnection circuit that substantially prevents barrel fractures in the conductive link.

### BRIEF DESCRIPTION OF THE DRAWINGS

The various features and advantages of this invention will become apparent to those skilled in the art from the following detailed description of the currently preferred embodiment. The drawings that accompany the detailed description can be briefly described as follows:

FIG. 1 is a perspective cross-sectional view of the dielectric plane with several metal layers;

FIG. 2 is a cross-sectional view of a multi-plane conductor levels;

FIG. 3 is a cross-sectional view of the dielectric plane with two conductor levels;

FIG. 4 is a cross-sectional view of the dielectric plane with a third conductor level;

FIG. 5 is a cross-sectional view of the dielectric plane with three conductor levels and a solder mask,

FIG. 6 is a cross-sectional view of an embodiment for fabrication of wire bonding locations; and

FIG. 7 is a cross-sectional view of another embodiment wire bonding locations.

### DETAILED DESCRIPTION OF THE PREFERRED EMBODIMENT

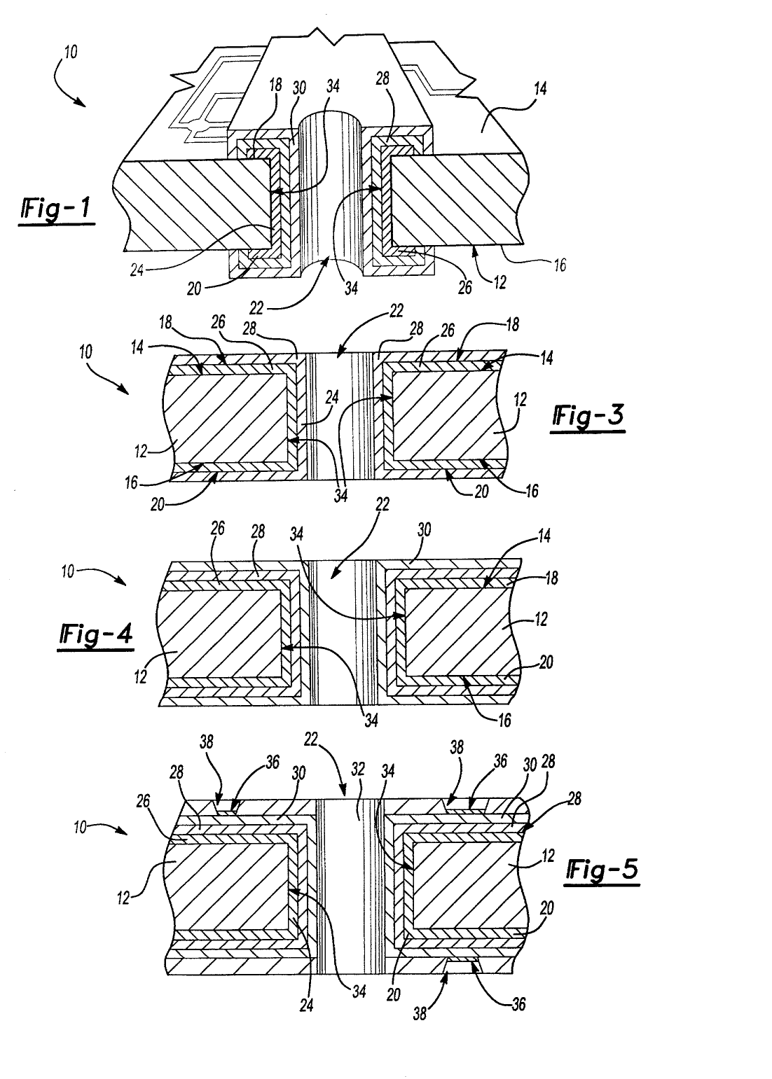

Referring to the Figures, wherein like numerals indicate like or corresponding parts throughout the several views, the subject invention is an interconnection circuit with a high strength via generally shown at 10 in FIG. 1. The assembly 10 includes a dielectric plane 12 having first 14 and second sides 16 and first 18 and second conductors 20 disposed on each of the sides 14, 16 of the dielectric plane 12. The conductors 18, 20 form a circuit pattern on each of the sides 14, 16 of the dielectric plane 12. An opening 22 through the dielectric plane 12 known in the art as a via, hole or plated through hole, provides for an electrical connection between the two conductors 18,20. The electrical connection is provided through a conductive link 24 formed from copper disposed on an inner wall 34 of the opening 22. The conductive link is the portion of copper disposed on the inner walls 34 of the opening 22, and the conductors 18,20 are the portions of copper that are disposed on the sides 14,16 of the dielectric plane 12 that are interconnected by conductive link 24. The conductors 18,20 and the conductive link 24 are formed from a first layer of copper 26.

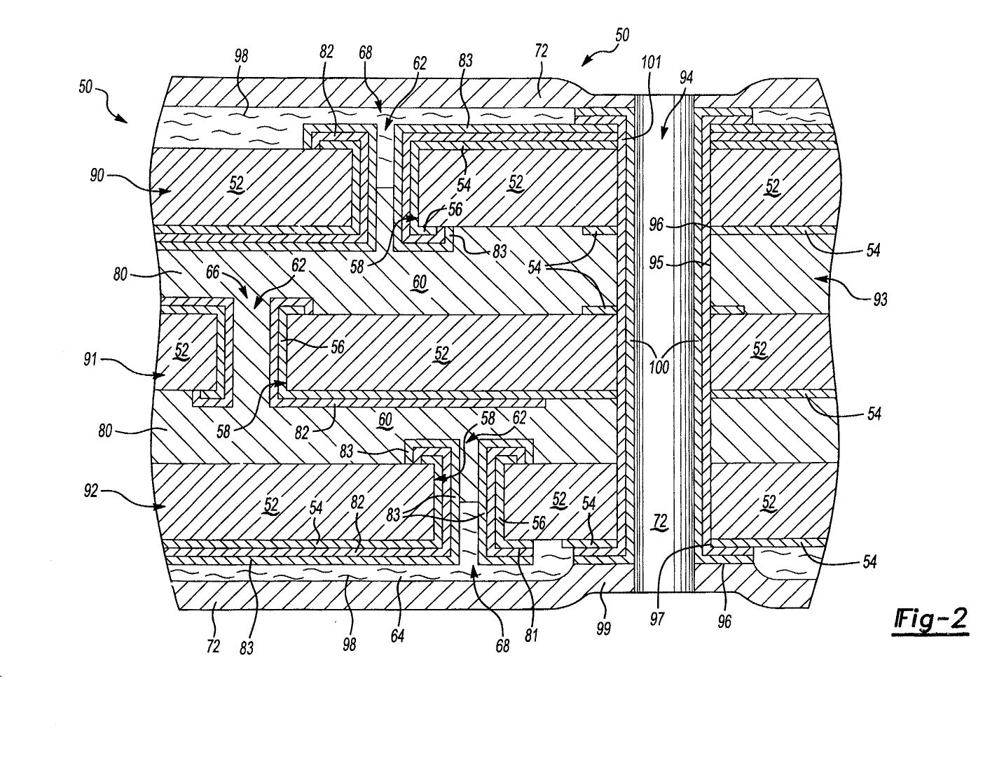

Referring to FIG. 2, another embodiment of this invention includes multiple dielectric planes 52 combined to form a high-density interconnection substrate 50. Preferably, the interconnected substrate 50 includes an initial layer of copper 54 applied to planar surfaces of each dielectric plane 52 after the formation of openings 62. This copper layer may be applied by a variety of means including electroless or autocatalytic plating, electroless or autocatalytic plating followed by electrolytic plating, thin film deposition of copper followed by electrolytic plating, and by other means known in the art. Thus this initial layer of copper 54 would also coat the sidewalls of openings 62. Depending upon the circuit function requirements, and the thickness of dielectric plane 52, copper layer 54 would preferably range from 2-70 micrometers.

Since it is common for power and ground connections to be comprised of relatively thick copper to minimize DC resistance, commonly 5-70 micrometers, if vias 66, 68 were making power or ground connections, it may be desirable for the via copper layer 54 thickness to be 5-70 micrometers. High frequency signal connections may only conduct in the outer layer of the copper conductor due to the skin effect. In these cases, the copper 54 conductors formed on the planar surfaces of dielectric 52 may only need to be 2-15 micrometers in thickness to meet performance objectives. In these cases, the via copper layer 54 thickness may be 2-10 micrometers in thickness. Medium frequency performance may require 10-30 micrometers in thickness to meet electrical performance criteria.

The desired conductor circuit pattern is then formed in the regions of copper layer 54 that coat the planar regions of dielectric plane 52. Nickel layer 82 is then plated over the circuit pattern formed in copper layer 54 to act as a strengthening member to prevent via cracking in the finished multilayer board 50 in buried vias 66 and blind vias 68. Nickel layer 82 may be applied by a variety of means including electroless or autocatalytic plating, electroless or autocatalytic plating followed by electrolytic plating, or electrolytic plating, and by other possible means known in the art.

The thickness of Nickel required to prevent barrel cracking in the vias 66, 68 is a function of the dielectric 52 thickness and the thermal expansion of the dielectric 52 parallel to the axis of the via. Most commonly used dielectric 52 thicknesses will range from 25-300 micrometers. Dielectric 52 thermal expansion parallel to the axis of the via may commonly range from 20-150 parts per million per degree Celsius. A nickel thickness range from 1-15 micrometers would be necessary to support this full range of dielectric 52 properties and thicknesses.

In most high performance cases, the thickness and thermal expansion of the dielectric 52 would permit the use of approximately 3-8 micrometers of nickel. The thermomechanical properties of the nickel are also a factor. Nickel deposits may vary considerable in chemistry, with significant amounts of other elements, such as phosphorous, sulphur, cobalt, and the like, plating with the Nickel. Also, variations in the Nickel plating process parameters, including temperature, pH, concentrations of key ions in the plating solution, anode—cathode geometry, and current levels and local region current densities, can significantly effect the nickel properties. Through manipulation of the plating solution chemistry and plating parameters is possible to deposit a nickel film that is in tension, compression, or is neutral at the plane of contact with the copper. Thus it is desirable to deposit a nickel deposit with optimized mechanical properties, where the nickel is in modest compression at the interface with the copper in the via. Before lamination of the three finished planes 90, 91, 92 shown in FIG. 2, and immediately after the plating of Nickel layer 82, outer planes 90, 92 of multilayer board 50 which contain blind vias 68 are plated to form a third layer of metal 83. Metal layer 83 is provided only to prevent oxidation of the underlying metal layer 82. Metal layer 83 is preferably copper, but may be any other metal which prevents oxidation of underlying layer 82 such as gold, palladium, silver, or tin. Metal layer 83 preferably does not oxidize or has an oxide, which is readily removed by standard processes well, known in the art.

In practice it may also be desirable to completely remove metal layer 83 in desired locations to expose clean, unoxidized surface of metal layer 82 prior to the application of a final finishing metal layer. Metal layer 83 is not needed on inner plane 91 which may contain buried vias 66 since electronic components will not be making bonds with metal features in the planar surfaces of metal planes 82 on these inner planes. In FIG. 2, the three finished planes 90, 91, 92 are then laminated together in precise registry using lamination material 80. Lamination material 80 may be an epoxy, a bismaleimide-triazine resin, a fiberglass-reinforced epoxy, a fiberglass reinforced bismaleimide-triazine, or other types of polymers or reinforced polymers.

After lamination, multilayer board 50 is partially finished with the creation of laminate 93, comprised of planes 90,91,92. Several process sequences may be followed to finish multilayer board 50, and one such process is described herein. The planar surfaces of laminate 93 may then be coated with resist 98 which is patterned to create apertures 99 through the resist layer 98 in desired locations. Openings 94 are then formed through laminate 93, generally within the apertures 99 in the resist layer 98. Laminate 93 is then processed to form a copper layer 96 on the sidewalls 95 of openings 94. Copper layer 96 also coats the annular regions 97 of copper layer 54 exposed through apertures 99, and which encircle the top and bottom of opening 94. A nickel strengthening layer 100 is then formed over the surface of copper layer 96. The metal layers 96 and 100 form electrical connections through laminate 93 by forming metallurgical bonds with the regions of copper plane 54, 83 and nickel plane 82 which are exposed in the sidewall of opening 94. Such a region 101 is seen in FIG. 2. A solder mask or resist layer 72 is then applied to the planar surfaces of laminate 93. The solder mask may also be used to fill the openings remaining in the metalized bore of opening 94.

The opening 62 provides electrical communication between conductors disposed on various planes 52 within the circuit arrangement. Buried-vias 66 are buried within the substrate 50 inplane 91. Blind-vias 68 penetrate only through outerplanes 90,92. Further, an opening 94 through the entire stack, large vias, allows interconnection between various dielectric planes 90,91,92 within the substrate 50. A worker skilled in the art would recognize that any type of via or electrical connection disposed between layers of one or several dielectric planes would benefit from application of this invention and are within the contemplation of this invention.

Referring to FIG. 3, the dielectric plane 12 is formed from a non-electrically conductive material that expands and contracts at a different rate than that of the copper material of the conductors 18,20 and the conductive link 24. The difference in expansion rates can cause fractures known by those in the art as barrel cracking. A second layer 28 of metal is disposed on to the conductors 18,20 and the conductive link 24 to strengthen the conductive link 24. The second layer 28 is composed of a material with higher strength characteristics than the first copper layer 26. Preferably the second layer 28 is composed of Nickel (Ni), however it is within the contemplation of this invention that other materials can be used. Deposition of the Ni layer is inexpensive. But the ferromagnetic property of Ni may make it undesirable for the Ni to cover all the conductors on the dielectric plane surfaces for some applications. To avoid this, it is possible to pattern a photosensitive polymer resist layer over the surface on the conductors on both sides of the dielectric plane. This photoresist may be patterned to create opening that only expose the copper where the Nickel is desired. It is critical that the Ni deposits uniformly over the copper down the sidewalls of all the openings 22 formed in dielectric layer 12. Since it is possible that photoresist residue in openings 22 may prevent uniform Ni plating over the copper on the sidewalls of openings 22, this process may not be desired. Thus it may be desirable to plate an alternative metal that is not ferromagnetic, or that has some other useful properties, but that still provides strengthening to the copper sidewall of openings 22, preventing barrel cracking.

The Ni layer 28 is applied over the first copper layer 26 in a plating process as is known in the art. This second layer, comprised of Ni 28 prevents barrel cracking in the conductive link 24. A worker knowledgeable in the art will recognize that Ni oxidizes quickly and such oxidation on a Ni layer is difficult to remove using normal processes. In some applications oxidation of the Ni layer 28 is acceptable and the Ni layer 28 can be the final coating. However, in applications where secondary electrical connections need to be made to the conductors 18,20, oxidation on the second Ni layer 28 would be unacceptable.

Referring to FIG. 4, another embodiment of the invention is shown with a third layer 30 deposited over the second layer 28 to prevent oxidation of the second layer 28. The third layer 30 may composed of non-corroding metals known in the art as Noble metals that include such Gold, Silver, Palladium and the like. Such metals also possess favorable bonding characteristics such that wire bonding and soldering are favorably accomplished. It is well known that Silver oxidizes readily, but the oxide is electrically conductive and is readily removed, so silver is included in this list of candidate materials.

Referring to FIG. 5, in another embodiment of this invention, the third layer 30 is composed of a non-noble metal that can be easily cleaned of oxidation or removed entirely. Preferably copper is used, however a worker knowledgeable in the art would recognize that other metals can be substituted. The use of the non-noble element avoids oxidation of the second layer 28 formed of Ni and reduces the cost of coating all of the conductor 18,20 with expensive metals such as Gold (Au). Preferably, when copper is used as the third layer 30, a noble metal (preferably Au) will be deposited in specific discrete locations 36 where a wire will be bonded or a contact will be soldered to the conductors 18,20.

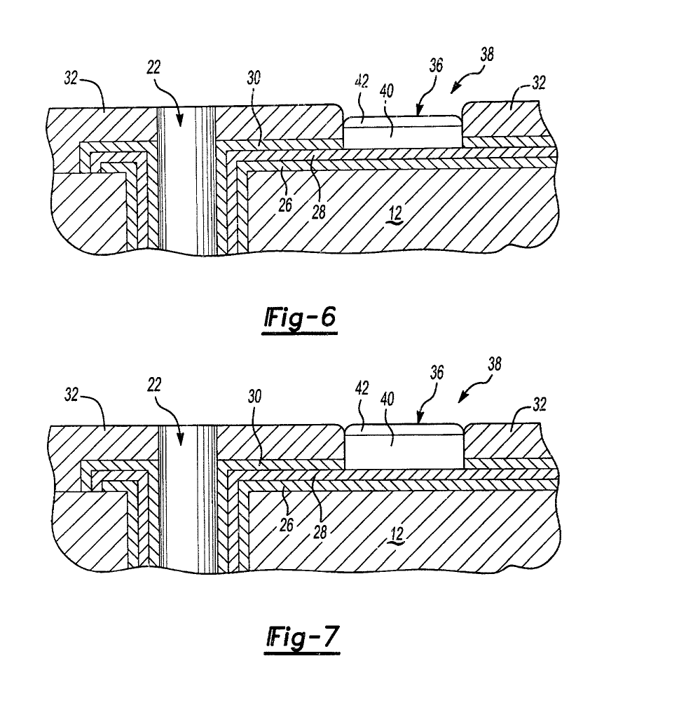

Referring to FIGS. 6 and 7, a solder mask 32 is deposited over the entire interconnection circuit and through the opening 22, essentially filling the opening 22. The solder mask 32 includes specific discrete openings 38 coinciding with the locations 36 where it is desired to deposit the final, readily bondable metal layer on the conductors 18, 20. Once the solder mask is processed to form said discrete openings, the surface of the third metal layer 30, which is copper in this embodiment, is exposed. In subsequent processing, the copper oxide surface is removed, some (FIG. 6) or all (FIG. 7) of the layer 30 copper is removed, and typically a thin layer 40 of Ni followed by an even thinner layer 42 of Au is plated. This Ni layer 40 thickness may typically be 0.5 micrometers to 10 micrometers, and the Au layer 42 preferably is of a thickness between 0.1 micrometers to 5 micrometers.

Referring to FIGS. 1 and 3-5, the subject invention also includes a method of fabricating the conductor circuit onto the dielectric planel2. The method includes the steps of applying the first layer of copper to form the first conductor 18 on the first side 14 of the dielectric plane, applying a layer of copper 26 to form the second conductor 20 and applying the first layer of material to form an electrical connection between the first and second conductors 18,20 including the conductive link 24 extending through the opening 22 and in electrical contact with the first and second conductors 18,20. At least one additional layer of metal is then applied over the conductive link 24 within the opening 22. A second layer 28, preferably of Nickel is then applied over the conductive link 24. In the first embodiment of the subject method the Nickel layer 28 is the final layer applied over the conductive link 24.

In another embodiment of the method, the third layer is applied over the second Nickel layer 28, to inhibit corrosion. Preferably this metal is gold, however, any non-corroding noble metal can be used.

In still another embodiment of the method a corroding metal that is easily removed or cleaned of corrosion is used to reduce the expense of providing an entire layer of an expensive noble metal such as gold. Preferably copper is used as the non-noble metal to be applied over the Nickel layer. However, other materials as is known to a worker skilled in the art can be used, such as tin.

In this embodiment a noble metal, such as gold, is deposited in discrete locations to facilitate the bonding of electrical connectors to the conductors 18,20. The method also includes the application of a solder mask over the surface of the entire interconnection circuit and through the opening 22. Preferably, the solder mask is deposited over the surface of the interconnection to define the discrete locations of oxidized copper. The copper is then deoxidized before cleaning and plating with nickel and gold. The solder mask defines a plurality of opening corresponding to the discrete locations to which electrical connections are to be made to the conductors 18,20.

In yet another embodiment, after the via plating, the via opening 22 is filled with a polymer material with a lower thermal expansion than that of the solder mask. The polymer material will loaded with low thermal expansion filler particulates, where preferably, the fillers are ceramic or glass particles, or particles of tetraflorethylene and the like.

The foregoing description is exemplary and not just a material specification. The invention has been described in an illustrative manner, and should be understood that the terminology used is intended to be in the nature of words of description rather than of limitation. Many modifications and variations of the present invention are possible in light of the above teachings. The preferred embodiments of this invention have been disclosed, however, one of ordinary skill in the art would recognize that certain modifications are within the scope of this invention. It is understood that within the scope of the appended claims, the invention may be practiced otherwise than as specifically described. For that reason the following claims should be studied to determine the true scope and content of this invention.

What is claimed is:

1. A interconnection circuit comprising;
a dielectric plane having a first side, an opposite second side, and an opening disposed through said dielectric plane
a first conductor disposed on said first side
a second conductor disposed on said second side;
an electrical connection between said first and second conductors including a conductive link extending through said opening and in electrical contact with said first and second conductors; and
at least one additional layer of metal disposed within said opening, where said additional layer is a different material from said conductive link.

2. The assembly of claim 1, wherein said dielectric plane includes an inner wall defining said opening and said conductive link is disposed on said inner wall.

3. The assembly of claim 2, wherein said conductive link is fabricated from the same material as the conductor disposed on said first and second sides of said dielectric plane.

4. The assembly of claim 3, wherein said conductive link and said conductor are copper.

5. The assembly of claim 1, wherein said additional layer of material nickel.

6. The assembly of claim 3, wherein said conductive link further includes a third layer of metal disposed over said second layer to provide corrosion resistance to said second layer of metal.

7. The assembly of claim 6, wherein said third layer is gold.

8. The assembly of claim 6, where said third layer is silver.

9. The assembly of claim 6, wherein said third layer is copper.

10. The assembly of claim 9, further including discrete deposits of gold disposed on said conductor to facilitate the bonding of an electrical connection to said conductors.

11. The assembly of claim 1, wherein a solder mask covers said layers of metal.

12. The assembly of claim 11, wherein said solder mask includes at least one opening to allow access to for and electrical connection to said conductors.

13. A interconnection circuit comprising;
a dielectric plane having first and second sides, and a conductive pattern fabricated from copper disposed on each of said first and second sides of said dielectric plane;
an opening disposed through said dielectric plane including a conductive link between said conductive pattern disposed on said sides of said dielectric plane;
said conductive link including a first layer fabricated from copper and a second layer, disposed over said first layer, fabricated from nickel to strengthen said first layer.

14. The assembly of claim 13, further including a third layer, disposed over said second layer to protect said second layer from corrosion.

15. The assembly of claim 14, wherein said third layer is fabricated from a noble metal.

16. The assembly of claim 14, wherein said third layer is fabricated from a non-noble metal that is easily cleaned of oxidation.

17. The assembly of claim 14, further including a solder mask having openings to provide access for electrical connections to said conductors.

18. A method of fabricating a interconnection circuit comprising the steps of;
a. applying a first layer of material to a dielectric plane form a first conductor disposed on a first side of the dielectric plane;
b. applying the first layer of material to from a second conductor disposed on a second side of the dielectric plane;
c. applying the first layer of material to an opening in the dielectric plane to form an electrical connection between said first and second conductors including a conductive link extending through said opening and in electrical contact with said first and second conductors;
d. applying at least one additional layer of metal over said first layer within said opening, wherein said additional layer is a different material from said conductive link to strengthen said conductive link.

19. The method of claim 18, wherein said step of applying at least one additional layer of material if further defined by applying a first additional layer over said conductive link.

20. The method of claim 19, wherein said step of applying at least one additional layer of material is further defined by applying a second additional layer over said first additional layer.

21. The method of claim 18, further including the step of applying a solder mask over said additional layers.

22. The method of claim 21, wherein the step of applying said solder mask is further defined by providing a plurality of discrete opening through said solder mask to provide for electrical connections to said first and second conductors

23. The method of claim 18, wherein said conductors are copper.

24. The method of claim 19, wherein said first additional layer is nickel.

25. The method of claim 20, wherein said second additional layer is gold.

26. The method of claim 20, wherein said second additional layer is copper.

27. The method of claim 26, wherein said second additional layer of copper includes discrete locations of gold for making electrical connections.
